(19) United States
(12) Patent Application Publication
(10) Pub. No.: US 2024/0385350 A1
(43) Pub. Date: Nov. 21, 2024

(54) OPTICAL THIN FILM MATERIALS, PREPARATION METHODS THEREOF, AND DISPLAY PANELS

(71) Applicant: Shenzhen China Star Optoelectronics Semiconductor Display Technology Co., Ltd., Shenzhen (CN)

(72) Inventor: Aibing BAO, Shenzhen (CN)

(73) Assignee: Shenzhen China Star Optoelectronics Semiconductor Display Technology Co., Ltd., Shenzhen (CN)

(21) Appl. No.: 18/361,849

(22) Filed: Jul. 30, 2023

(30) Foreign Application Priority Data
May 15, 2023 (CN) 202310546143.1

(51) Int. Cl. G02B 1/04; H10K 85/40; H10K 85/60

(52) U.S. Cl. CPC G02B 1/04; H10K 85/40; H10K 85/60

(57) ABSTRACT

An optical thin film material including a compound represented by the following formula (1), in which one of R₁ and R₂ includes an aromatic ring and/or a sulfur atom, and another of R₁ and R₂ includes at least one of an acryloyloxy group, an aromatic ring, and a sulfur atom.

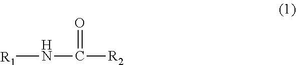

### CROSS-REFERENCE TO RELATED APPLICATION

The present disclosure claims priority to and the benefit of Chinese Patent Application No. 202310546143.1 filed on May 15, 2023, the disclosure of which is incorporated herein by reference in its entirety.

### TECHNICAL FIELD

The present disclosure relates to display technology, in particular to optical thin film materials, preparation methods thereof, and display panels.

### BACKGROUND

At present, in sensors, displays and other devices, high refractive index polymer materials are often used to improve optical sensing effects and display effects.

In the related art, halogen atoms or nanoparticles can be used to improve the refractive index of the material. However, the use of the halogen atoms is limited because of toxicity and corrosive gases generated during the combustion of the material containing the halogen atoms. Moreover, nanoparticles are not dispersed and stable in polymers, and when applied to optical devices, nanoparticles are prone to scattering, which in turn affects the optical properties of the device.

### SUMMARY

Embodiments of the present disclosure provide an optical thin film material including a compound, in which the compound is represented by formula (1):

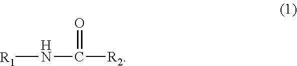

In the formula (1), one of R₁ and R₂ includes an aromatic ring and/or a sulfur atom, and another of R₁ and R₂ includes at least one of an acryloyloxy group, an aromatic ring, and a sulfur atom.

Embodiments of the present disclosure provide a preparation method of an optical thin film, which includes following steps: providing an optical thin film material including a compound, in which the compound is represented by formula (1):

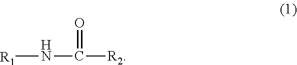

In the formula (1), one of R₁ and R₂ includes an aromatic ring and/or a sulfur atom, and another of R₁ and R₂ includes at least one of an acryloyloxy group, an aromatic ring, and a sulfur atom; and forming the optical thin film using the optical thin film material.

Embodiments of the present disclosure further provide a display panel, which includes an optical thin film prepared using the above-mentioned preparation method of the optical thin film.

### BRIEF DESCRIPTION OF DRAWINGS

FIG. 1 is a flowchart of a preparation method of an optical thin film according to one or more embodiments of the present disclosure.

FIG. 2 is a schematic structural diagram of a display panel according to one or more embodiments of the present disclosure.

### DETAILED DESCRIPTION OF EMBODIMENT

In combination with drawings in the embodiments of the present disclosure, technical solutions in the embodiments of the present disclosure will be described clearly and completely. Apparently, the described embodiments are only part of the embodiments of the present disclosure, not all of them. Based on the embodiments of the present disclosure, all other embodiments obtained by those skilled in the art without creative effort belong to a scope of the present disclosure.

The following disclosure provides many different implementation methods or examples to implement different structures of the present disclosure. In order to simplify the present disclosure, specific examples of components and arrangement will be described below. Of course, they are only examples and are not intended to limit the present disclosure. In addition, reference numbers and/or reference letters may be repeated in different examples of the present disclosure for the purpose of simplification and clarity, which does not indicate the relationship between the various embodiments and/or arrangement discussed. Moreover, the present disclosure provides examples of various specific processes and materials, but those skilled in the art may be aware of other processes and/or the use of other materials.

Embodiments of the present disclosure provide an optical thin film material including a compound, and the compound is represented by the following formula (1):

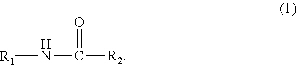

In the formula (1), one of R₁ and R₂ includes an aromatic ring and/or a sulfur atom, and another of R₁ and R₂ includes at least one of an acryloyloxy group, an aromatic ring, and a sulfur atom.

The optical thin film material provided by the embodiments of the present disclosure can be used to form an optical thin film with higher refractive index by introducing the aromatic ring and/or the sulfur atom to effectively improve the refractive index of the optical thin film material. Moreover, since none of halogen atoms and nanoparticles are introduced in the optical thin film material, the present disclosure avoids the halogen atoms being restricted for use due to toxicity and corrosive gases generated during the combustion of the material containing the halogen atoms, and eliminates the adverse effects of the nanoparticles on light scattering.

Specifically, the optical thin film material may be polymer. The refractive index of the polymer is defined as n, the molar refractive index of a repeating unit of the polymer is defined as R_{M}, and the molar volume of the repeating unit of the polymer is defined as V_{M}, and n, R_{M}, and V_{M} satisfy the following equation:

$$n = \sqrt{\frac{1 + 2 ( {R}_{M} / {V}_{M} )}{1 - ( {R}_{M} / {V}_{M} )}} .$$

The above-mentioned equation can be used to predict the refractive index of the polymer.

In the above-mentioned equation, the molecular refractive index of the repeating unit of the polymer is defined as R, the relative molecular mass of the repeating unit of the polymer is defined as M, R/M is defined as the molar refractive index RM of the repeating unit of the polymer, which indicates a sum of refractive indexes of atoms and functional groups that constitute the repeating unit of the polymer. The molecular volume of the repeating unit of the polymer is defined as V, and V/M is defined as the molar volume V_{M} of the repeating unit of the polymer. The molar refractive index R_{M} of each atom and each group in the polymer are shown in table 1.

TABLE 1

| Atom/Group | R_{M} | Atom/Group | R_{M} |
|---|---|---|---|
| Hydrogen (H) | 1.100 | Phenyl (C₆H₅) | 25.463 |
| Carbon (C) | 2.418 | Naphthyl (C₁₀H₇) | 43.00 |
| Double bond (C═C) | 1.733 | Chlorine (Cl) | 5.967 |
| Triple bond (C═C) | 2.398 | Bromine (Br) | 8.865 |
| Carbonyl (C═O) | 2.211 | Iodine (I) | 13.900 |
| Hydroxyl (—OH) | 1.525 | Thiocarbonyl (C═S) | 7.97 |
| Ether (—C—O—) | 1.643 | Thiol (—SH) | 7.69 |
| fluorine (F) | 0.95 | Dithia (—S—S—) | 8.11 |

It can be seen from table 1 that the aromatic ring such as C₆H₅ and C₁₀H₇, halogen atoms other than fluorine such as Cl, Br, and I, and sulfur atom all have higher molar refractive index, which can effectively improve the refractive index of the polymer containing the aforementioned groups.

Based on the above, the optical thin film material provided by the embodiments of the present disclosure can be used to form an optical thin film with higher refractive index by introducing the aromatic ring and/or the sulfur atom having higher molar refractive index in the compound represented by the formula (1). Moreover, the embodiments of the present disclosure can avoid the use of halogen atoms, avoiding the phenomenon of being restricted for use due to toxicity and corrosive gases generated during the combustion of the material containing the halogen atoms.

Furthermore, in some embodiments of the present disclosure, the compound represented by the formula (1) may also include an acryloyloxy group, which can undergo cross-linking polymerization reactions in the formation of the polymer to improve cross-linking degree.

In some embodiments, both of R₁ and R₂ include at least one acryloyloxy group, which can effectively improve the cross-linking degree of the polymer in the cross-linking polymerization reaction for forming the polymer, so as to improve the mechanical performance and stability of the optical thin film prepared by the optical thin film material, and improve its resistance to high and low temperature, high temperature and humidity, and cold and hot shock.

In some embodiments, the optical thin film material may include at least one of a first compound, a second compound, and a third compound. Specifically, the first compound is represented by following structure:

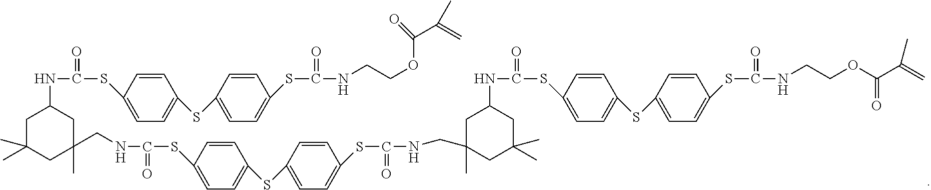 [SMILES: C=C(C)C(=O)OCCNC(=O)Sc1ccc(Sc2ccc(SC(=O)NC3CC(C)(C)CC(C)(CNC(=O)Sc4ccc(Sc5ccc(SC(=O)NCC6(C)CC(NC(=O)Sc7ccc(Sc8ccc(SC(=O)NCCOC(=O)C(=C)C)cc8)cc7)CC(C)(C)C6)cc5)cc4)C3)cc2)cc1]

In some embodiments, R₁ in the formula of the first compound may be

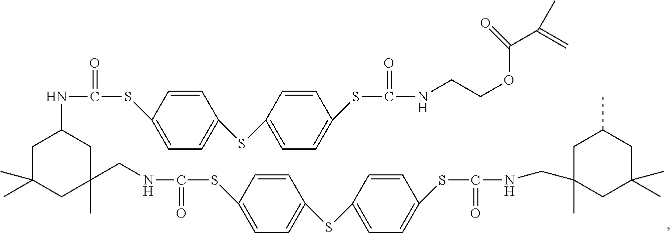

and R₂ in the formula of the first compound may be

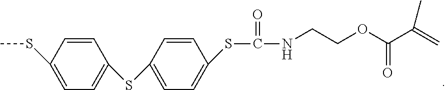

In the first compound, both of R₁ and R₂ have a large number of sulfur atoms and aromatic rings, making a higher molar refractive index of the first compound, which can effectively improve the refractive index of the optical thin film made of the optical thin film material including the first compound.

The second compound is represented by following structure:

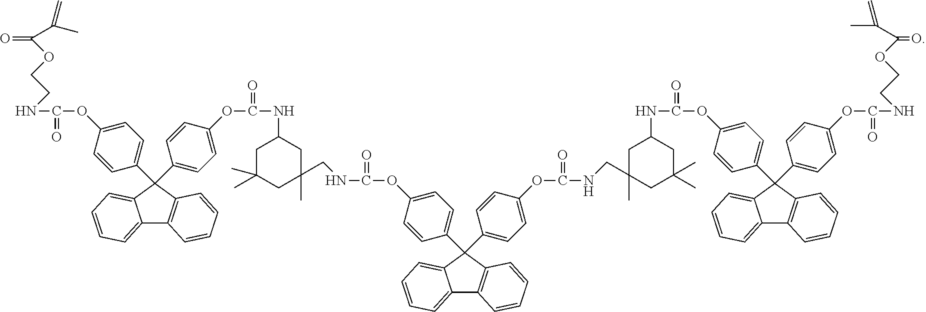 [SMILES: C=C(C)C(=O)OCCNC(=O)Oc1ccc(C2(c3ccc(OC(=O)NC4CC(C)(C)CC(C)(CNC(=O)Oc5ccc(C6(c7ccc(OC(=O)NCC8(C)CC(NC(=O)Oc9ccc(C%10(c%11ccc(OC(=O)NCCOC(=O)C(=C)C)cc%11)c%11ccccc%11-c%11ccccc%11%10)cc9)CC(C)(C)C8)cc7)c7ccccc7-c7ccccc76)cc5)C4)cc3)c3ccccc3-c3ccccc32)cc1]

In some embodiments, R₁ in the formula of the second compound may be

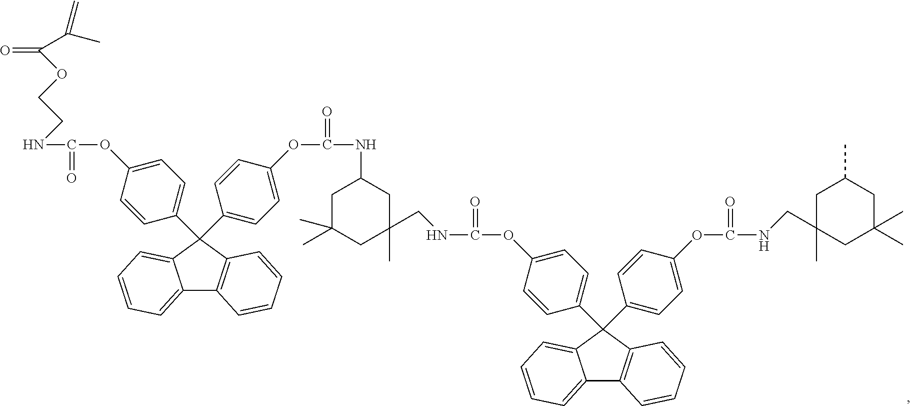

and R₂ in the formula of the second compound may be

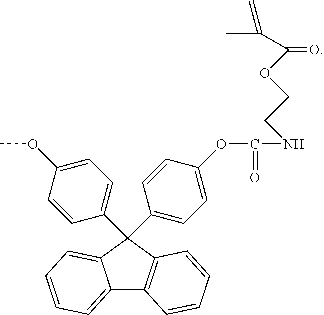

Compared to the first compound, there are more aromatic rings in both of R₁ and R₂ in the second compound. The second compound has higher molar refractive index to effectively improve the refractive index of the optical thin film made of the optical thin film material including the first compound and the second compound.

The third compound is represented by following structure:

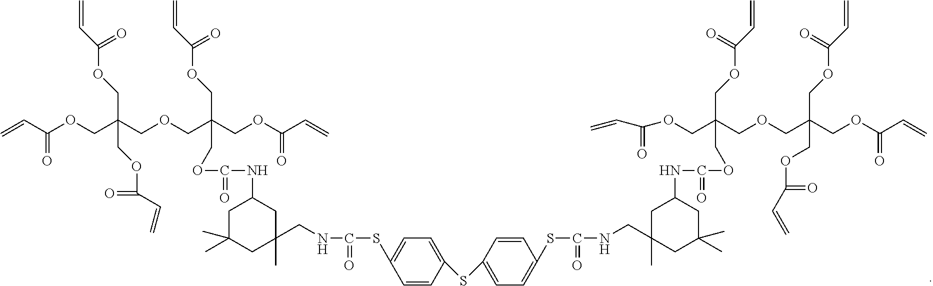 [SMILES: C=CC(=O)OCC(COCC(COC(=O)C=C)(COC(=O)C=C)COC(=O)NC1CC(C)(C)CC(C)(CNC(=O)Sc2ccc(Sc3ccc(SC(=O)NCC4(C)CC(NC(=O)OCC(COCC(COC(=O)C=C)(COC(=O)C=C)COC(=O)C=C)(COC(=O)C=C)COC(=O)C=C)CC(C)(C)C4)cc3)cc2)C1)(COC(=O)C=C)COC(=O)C=C]

In some embodiments, R₁ in the formula of the third compound may be

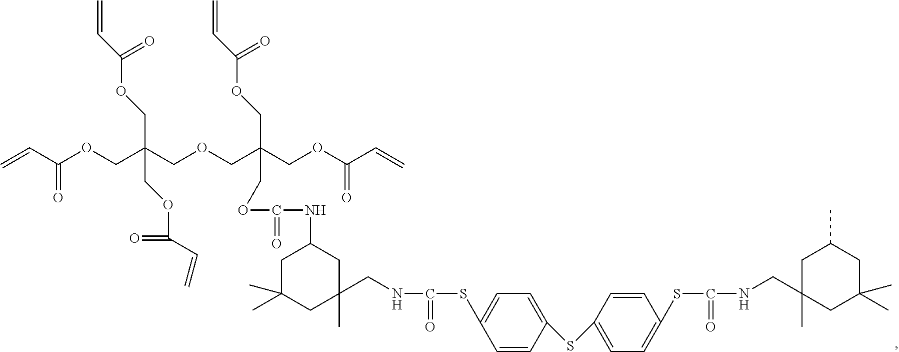

and R₂ in the formula of the third compound may be

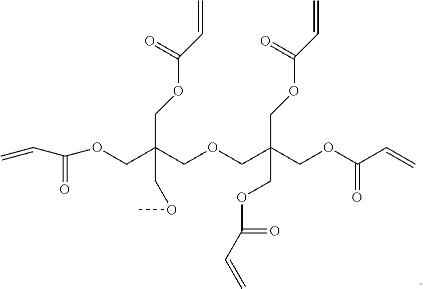

In the third compound, R₁ contains aromatic rings and sulfur atoms, making the third compound have higher molar refractive index, and further improving the refractive index of the optical thin film made of the optical thin film material including the first compound, the second compound, and the third compound. Moreover, both of R₁ and R₂ in the third compound contain a large number of acryloyloxy groups, which can effectively improve the cross-linking degree of the third compound and the first compound and the second compound in the cross-linking polymerization reaction for forming the optical thin film, improving the mechanical performance and stability of the optical thin film made of the optical thin film material including these compounds, and further improving its resistance to high and low temperature, high temperature and humidity, and cold and hot shock.

Furthermore, the first compound may be contained in the optical thin film material in an amount of 50 to 100 parts by mass, the second compound may be contained in the optical thin film material in an amount of 0 to 50 parts by mass, and the third compound may be contained in the optical thin film material in an amount of 0 to 50 parts by mass. For example, the first compound may be contained in the optical thin film material in an amount of 50, 60, 70, 80, 90, or 100 parts by mass; the second compound may be contained in the optical thin film material in an amount of 0, 10, 20, 30, 40, or 50 parts by mass, and the third compound may be contained in the optical thin film material in an amount of 0, 10, 20, 30, 40, or 50 parts by mass. The above values are examples of the first compound, the second compound, and the third compound within their respective mass ranges, but are not limited to this.

Furthermore, the optical thin film material is a photocurable material. In some embodiments, the optical thin film material further includes a photoinitiator, and in order to adjust the viscosity of the optical thin film material, the optical thin film material may include a reactive diluent.

In some embodiments, the reactive diluent includes a first reactive diluent containing a monofunctional group and/or a second reactive diluent containing a double functional group. For example, the first reactive diluent may be selected from hydroxyethyl (meth)acrylate, isobornyl (meth)acrylate, 2-phenoxyethyl acrylate, lauryl acrylate, tetrahydrofuran acrylate, or the like; and the second reactive diluent may be selected from di(ethylene glycol) diacrylate, tri(ethylene glycol) diacrylate, poly(ethylene glycol) diacrylate, di(propylene glycol) diacrylate, tri(propylene glycol) diacrylate, tricyclodecane dimethanol diacrylate, neopentyl glycol diacrylate, 1,6-hexanediol diacrylate, or the like.

The photoinitiator may include a I-type photoinitiator and/or an II-type photoinitiator. The I-type photoinitiator may be used to decompose molecules to generate free radicals due to differences in chemical structure or binding energy of the moleculars. Tertiary amines are introduced in the II-type photoinitiator (a hydrogen grabbing photoinitiator) as co initiators. Specifically, the I-type photoinitiator may be selected from an acetophenone-based photoinitiator and/or a benzoin-based photoinitiator. For example, the acetophenone-based photoinitiator may be selected from 4-phenoxydichlorophenone, 4-tert-butyl dichlorophenone, 4-tert-butyl trichlorophenone, diethoxyacetophenone, 2-hydroxy-2-methyl-1-phenylpropyl-1-one, 1-(4-isopropylphenyl)-2-hydroxy-2-methylpropyl-1-one, 1-(4-dodecylphenyl)-2-hydroxy-2-methylpropyl-1-one, 4-hydroxy (2-hydroxyethoxy) phenyl (2-hydroxy-2-propyl) ketone, 1-hydroxycyclohexyl phenyl ketone, or the like; and the benzoin-based photoinitiator may be selected from benzoin methyl ether, benzoin ethyl ether, benzyl dimethyl ketal, or the like. The II-type photoinitiator may be selected from a benzophenone-based photoinitiator and/or a thioxanthone-based photoinitiator. For example, the benzophenone-based photoinitiator may be selected from benzophenone, benzoylbenzoic acid, benzoylbenzoic acid methyl ether, 4-phenylbenzophenone, hydroxybenzophenone, 4-benzoyl-4′-methyldiphenyl sulfide, 3,3′-dimethyl-4-methoxybenzophenone, or the like; and the thioxanthone-based photoinitiator may be selected from thioxanthone, 2-chlorothioxanthone, 2-methylthioxanthone, 2,4-dimethylthioxanthone, isopropylthioxanthone, or the like. The photoinitiator of the present disclosure may be selected from at least one of the above-mentioned photoinitiators.

In some embodiments, the reactive diluent may be contained in the optical thin film material in an amount of 10 to 30 parts by mass, such as 10, 20, or 30 parts by mass. In some embodiments, the photoinitiator may be contained in the optical thin film material in an amount of 1 to 10 parts by mass, such as 1, 2, 3, 4, 5, 6, 7, 8, 9, or 10parts by mass. The above values are examples of the reactive diluent and the photoinitiator within their respective mass ranges, but are not limited to this.

In view of foregoing, the optical thin film material provided by the embodiments of the present disclosure can be used to form the optical thin film with higher refractive index by introducing the aromatic ring and/or the sulfur atom in the optical thin film material. Moreover, since none of halogen atoms and nanoparticles are introduced in the optical thin film material, the present disclosure avoids the halogen atoms being restricted for use due to toxicity and corrosive gases generated during the combustion of the material containing the halogen atoms, and eliminates the adverse effects of the nanoparticles on light scattering.

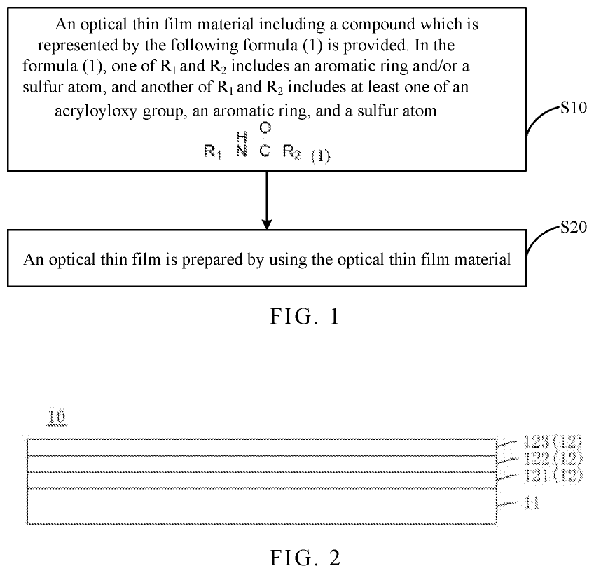

Furthermore, embodiments of the present disclosure further provide a preparation method of an optical thin film. Referring to FIG. 1, the preparation method of the optical thin film includes step S10 and step S20.

At step S10, an optical thin film material including a compound which is represented by the following formula (1) is provided.

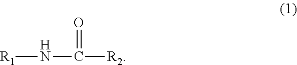

In the formula (1), one of R₁ and R₂ includes an aromatic ring and/or a sulfur atom, and another of R₁ and R₂ includes at least one of an acryloyloxy group, an aromatic ring, and a sulfur atom.

At step S20, the optical thin film is prepared by using the optical thin film material.

Specifically, at step S10, the optical thin film material may include at least one of a first compound, a second compound, and a third compound. Specifically, the first compound is represented by following structure:

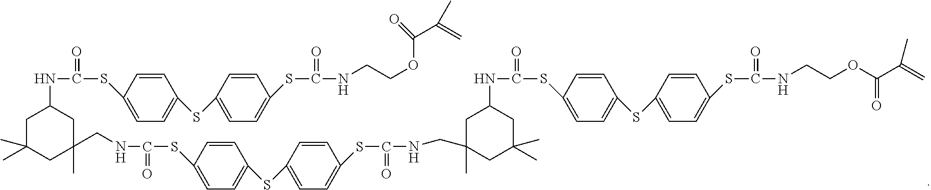 [SMILES: C=C(C)C(=O)OCCNC(=O)Sc1ccc(Sc2ccc(SC(=O)NC3CC(C)(C)CC(C)(CNC(=O)Sc4ccc(Sc5ccc(SC(=O)NCC6(C)CC(NC(=O)Sc7ccc(Sc8ccc(SC(=O)NCCOC(=O)C(=C)C)cc8)cc7)CC(C)(C)C6)cc5)cc4)C3)cc2)cc1]

In some embodiments, R₁ in the formula of the first compound may be

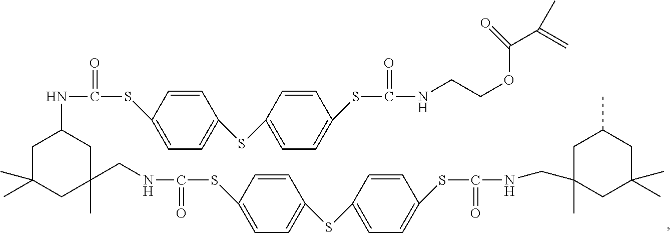

and R₂ in the formula of the first compound may be

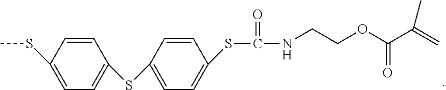

### The Synthetic Method of the First Compound

(1) Synthesis of Pre-polymer. 10 g of methyl ethyl ketone, 20 g of 4′,4-dithiodiphenylthioamidine, and 8.8 g of isophorone diisocyanate were added into a three-necked flask. The solution was stirred at a temperature of 60° C. for 10 minutes, then 0.1 g of dibutyl tin di lauric acid (DBTDL) was added into the solution as catalyst, and reacted at a temperature of 60° C. for 4 hours, to obtain the pre-polymer containing thiol groups respectively linked at two ends of the pre-polymer. The synthetic route of the pre-polymer is as follows:

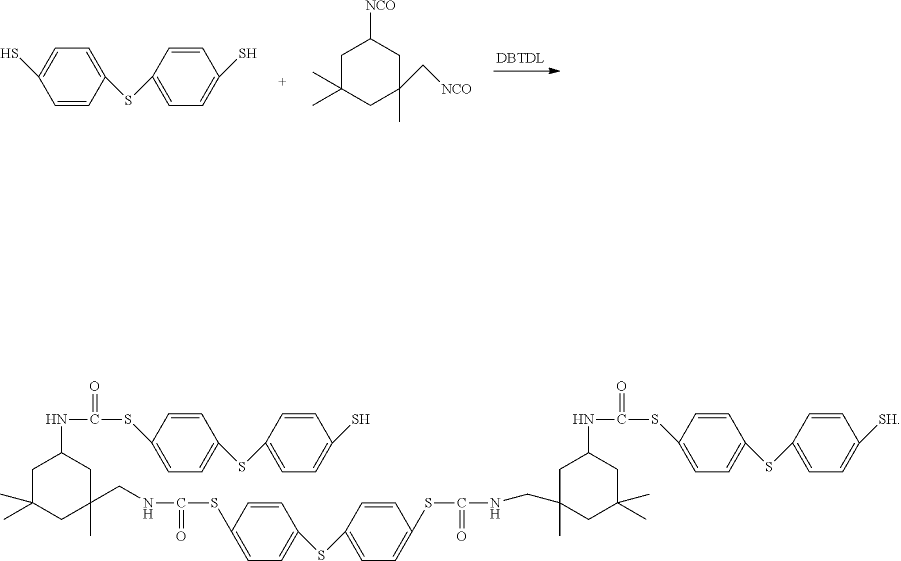

(2) Synthesis of the first compound. 10 g of methyl ethyl ketone, 20 g of pre-polymer, and 13 g of ethyl methacrylate isocyanate were added into a three-necked flask, and stirred at a temperature of 60° C. for 10 minutes. Then, 0.1 g of DBTDL was added into the solution as catalyst, and reacted at a temperature of 60° C. for 4 hours, to obtain the first compound containing acryloyloxy groups respectively linked at two ends of the first compound. The synthetic route of the first compound is as follows:

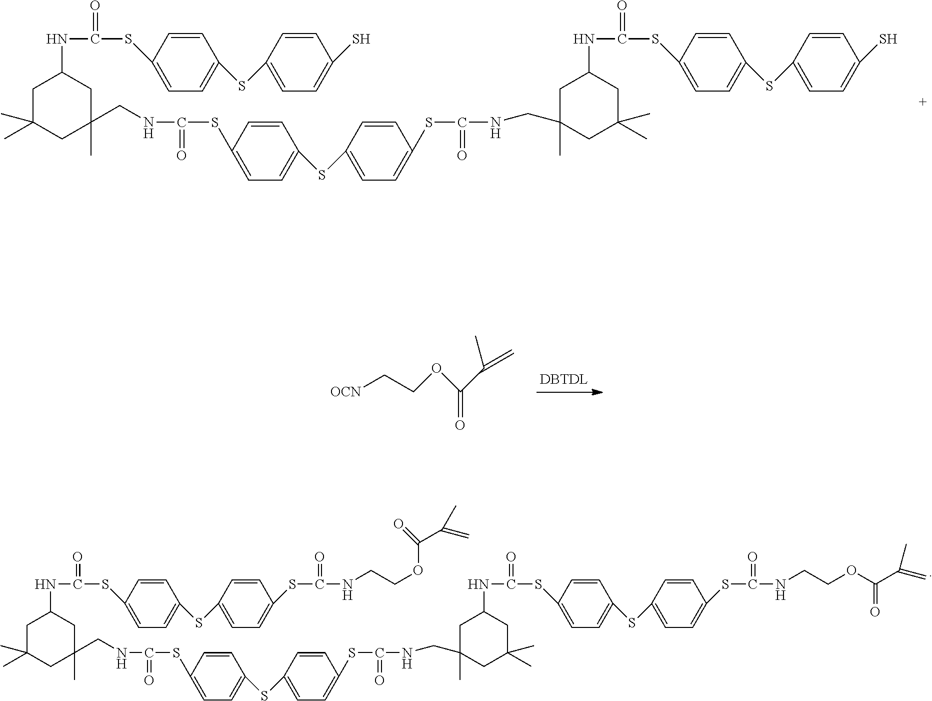

In the first compound, both of R₁ and R₂ have a large number of sulfur atoms and aromatic rings, making a higher molar refractive index of the first compound, which can effectively improve the refractive index of the optical thin film made of the optical thin film material including the first compound.

The second compound is represented by following structure:

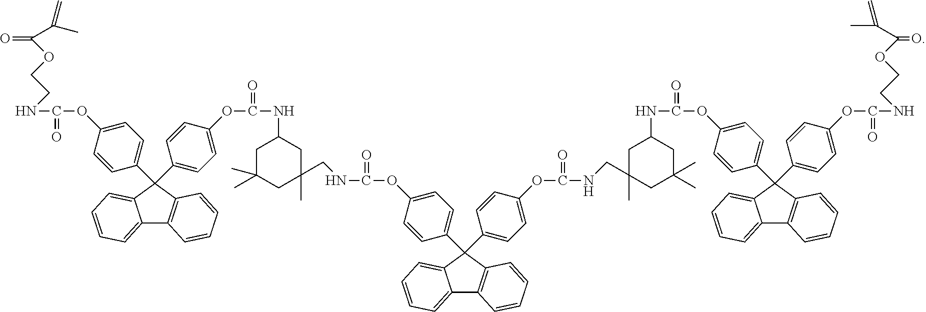 [SMILES: C=C(C)C(=O)OCCNC(=O)Oc1ccc(C2(c3ccc(OC(=O)NC4CC(C)(C)CC(C)(CNC(=O)Oc5ccc(C6(c7ccc(OC(=O)NCC8(C)CC(NC(=O)Oc9ccc(C%10(c%11ccc(OC(=O)NCCOC(=O)C(=C)C)cc%11)c%11ccccc%11-c%11ccccc%11%10)cc9)CC(C)(C)C8)cc7)c7ccccc7-c7ccccc76)cc5)C4)cc3)c3ccccc3-c3ccccc32)cc1]

In some embodiments, R₁ in the formula of the second compound may be

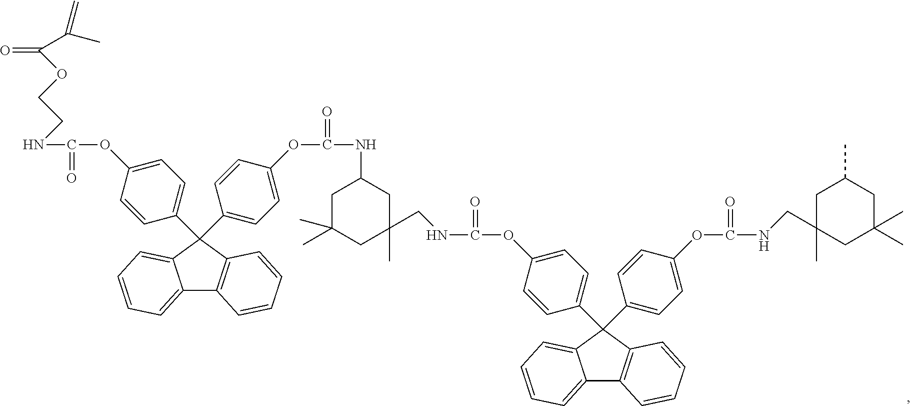

and R₂ in the formula

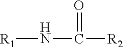

of the second compound may be

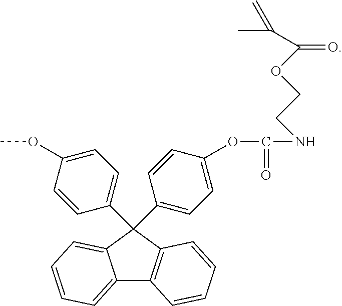

The second compound is represented by following structure:

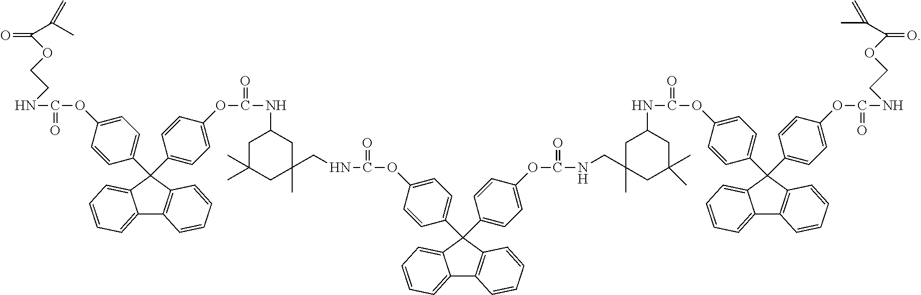 [SMILES: C=C(C)C(=O)OCCNC(=O)Oc1ccc(C2(c3ccc(OC(=O)NC4CC(C)(C)CC(C)(CNC(=O)Oc5ccc(C6(c7ccc(OC(=O)NCC8(C)CC(NC(=O)Oc9ccc(C%10(c%11ccc(OC(=O)NCCOC(=O)C(=C)C)cc%11)c%11ccccc%11-c%11ccccc%11%10)cc9)CC(C)(C)C8)cc7)c7ccccc7-c7ccccc76)cc5)C4)cc3)c3ccccc3-c3ccccc32)cc1]

### The Synthetic Method of the Second Compound

(1) Synthesis of Pre-polymer. 10 g of toluene, 20 g of 9′,9-bis (4-hydroxyphenyl) fluorene, and 5 g isophorone diisocyanate were added into a three-necked flask. The solution was stirred at a temperature of 60° C. for 10 minutes, then 0.1 g of DBTDL was added into the solution as catalyst, and reacted at a temperature of 60° C. for 4 hours, to obtain the pre-polymer containing hydroxyl groups respectively linked at two ends of the pre-polymer. The synthetic route of the pre-polymer is as follows:

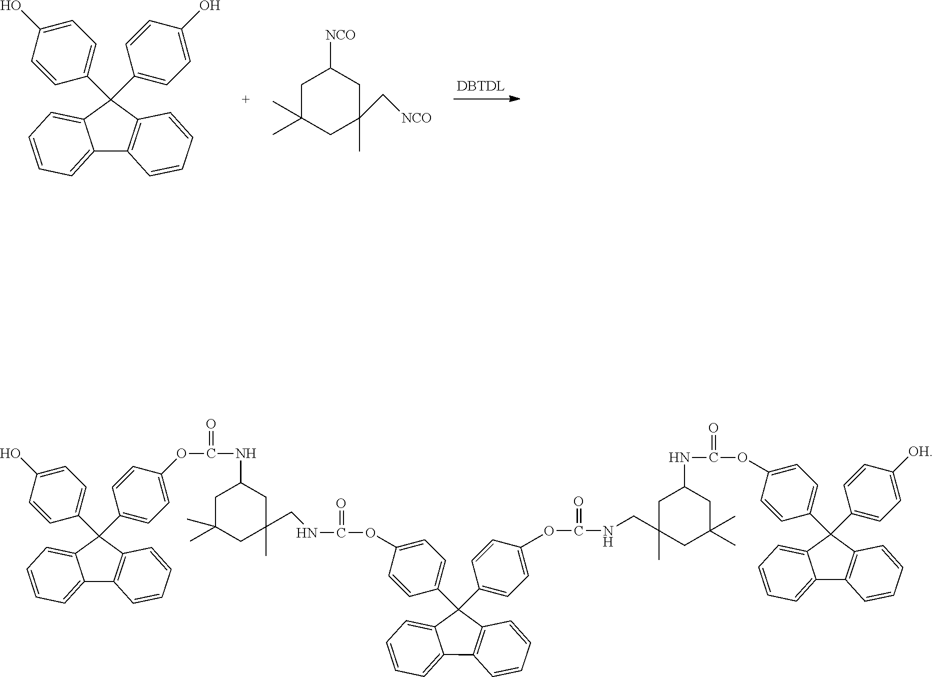

(2) Synthesis of the second compound. 10 g toluene, 20 g of pre-polymer, and 2.4 g ethyl methacrylate isocyanate were added into a three-necked flask, stirred at a temperature of 60° C. for 10 minutes. Then, 0.1 g of DBTDL was added into the solution as catalyst, and reacted at a temperature of 60° C. for 4 hours, to obtain the second compound containing acryloyloxy groups respectively linked at two ends of the second compound. The synthetic route of the second compound is as follows:

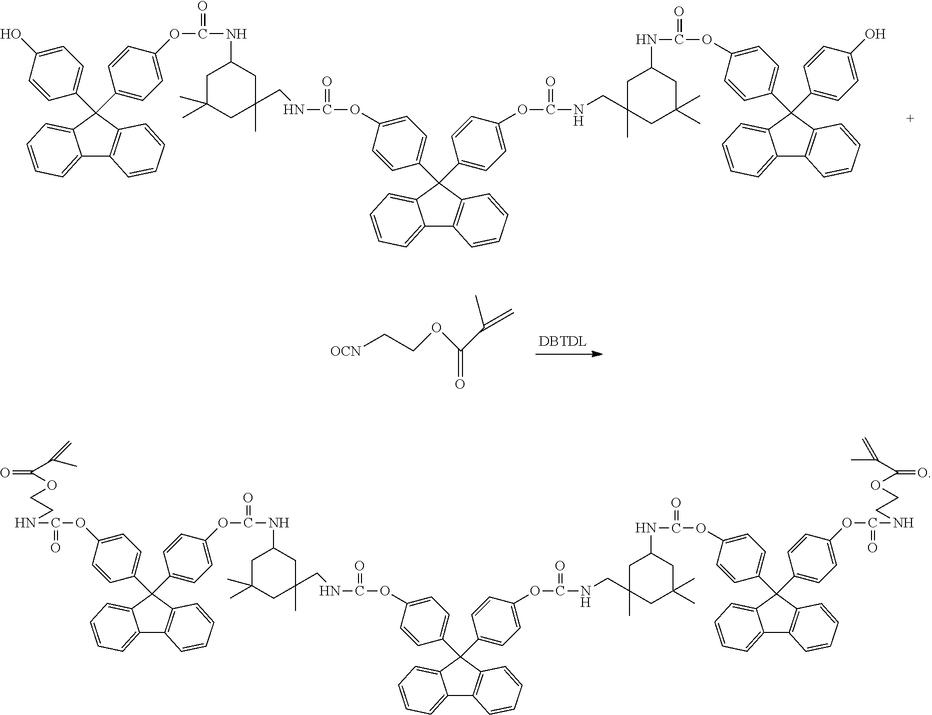

Compared to the first compound, there are more aromatic rings in both of R₁ and R₂ in the second compound. The second compound has higher molar refractive index to effectively improve the refractive index of the optical thin film made of the optical thin film material including the first compound and the second compound.

The third compound is represented by following structure:

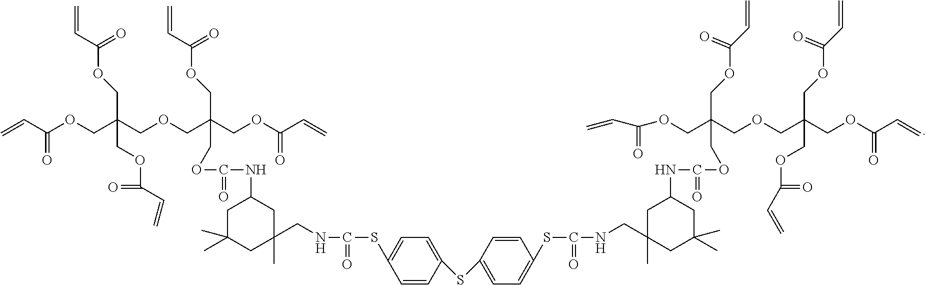 [SMILES: C=CC(=O)OCC(COCC(COC(=O)C=C)(COC(=O)C=C)COC(=O)NC1CC(C)(C)CC(C)(CNC(=O)Sc2ccc(Sc3ccc(SC(=O)NCC4(C)CC(NC(=O)OCC(COCC(COC(=O)C=C)(COC(=O)C=C)COC(=O)C=C)(COC(=O)C=C)COC(=O)C=C)CC(C)(C)C4)cc3)cc2)C1)(COC(=O)C=C)COC(=O)C=C]

In some embodiments, R₁ in the formula of the third compound may be

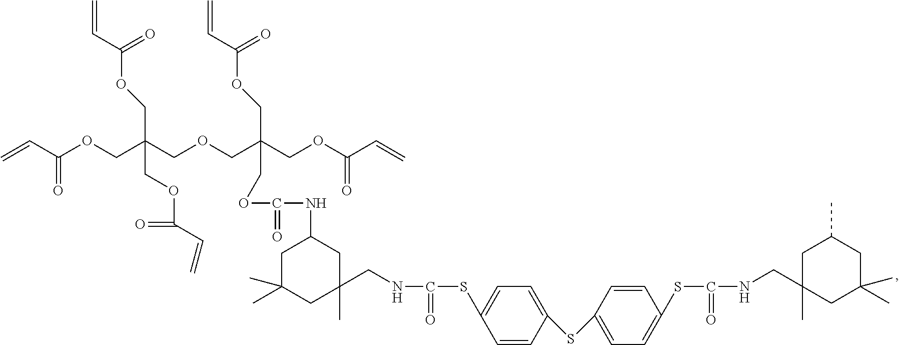 [SMILES: C=CC(=O)OCC(COCC(COC(=O)C=C)(COC(=O)C=C)COC(=O)NC1CC(C)(C)CC(C)(CNC(=O)Sc2ccc(Sc3ccc(SC(=O)NCC4(C)C[C@H](C)CC(C)(C)C4)cc3)cc2)C1)(COC(=O)C=C)COC(=O)C=C]

and R₂ in the formula of the third compound may be

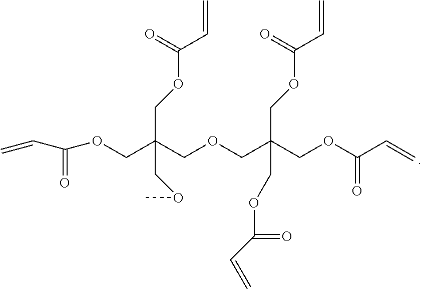

### The Synthetic Method of the First Compound

(1) Synthesis of Pre-polymer. 10 g of methyl ethyl ketone, 20 g of 4′,4-dithiodiphenylthioamidine, and 35 g of isophorone diisocyanate were added into a three-necked flask. The solution was stirred at a temperature of 60° C. for 10 minutes, then 0.1 g of DBTDL was added into the solution as catalyst, and reacted at a temperature of 60° C. for 4 hours, to obtain the pre-polymer containing isocyanate groups respectively linked at two ends of the pre-polymer. The synthetic route of the pre-polymer is as follows:

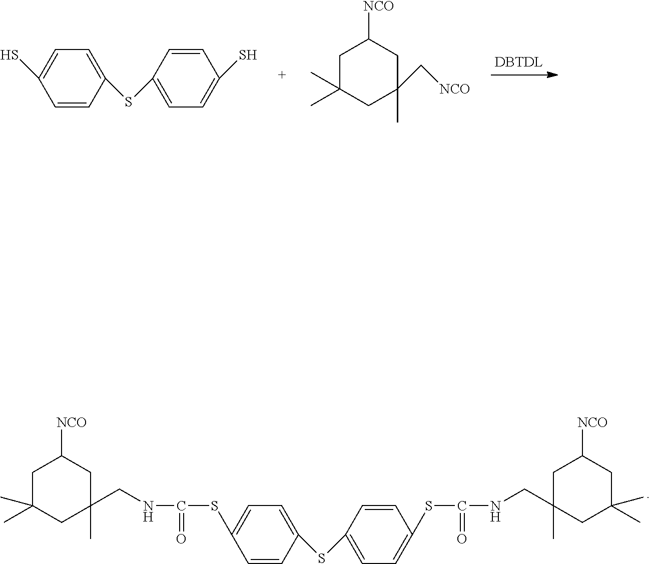

(2) Synthesis of the third compound. 10 g of methyl ethyl ketone, 20 g of pre-polymer, 25 g of dipentaerythritol pentaacrylate were added into a three-necked flask, and stirred at a temperature of 60° C. for 10 minutes. Then, 0.1 g of DBTDL was added into the solution as catalyst, and reacted at a temperature of 60° C. for 4 hours, to obtain the third compound containing acryloyloxy groups respectively linked at two ends of the third compound. The synthetic route of the third compound is as follows:

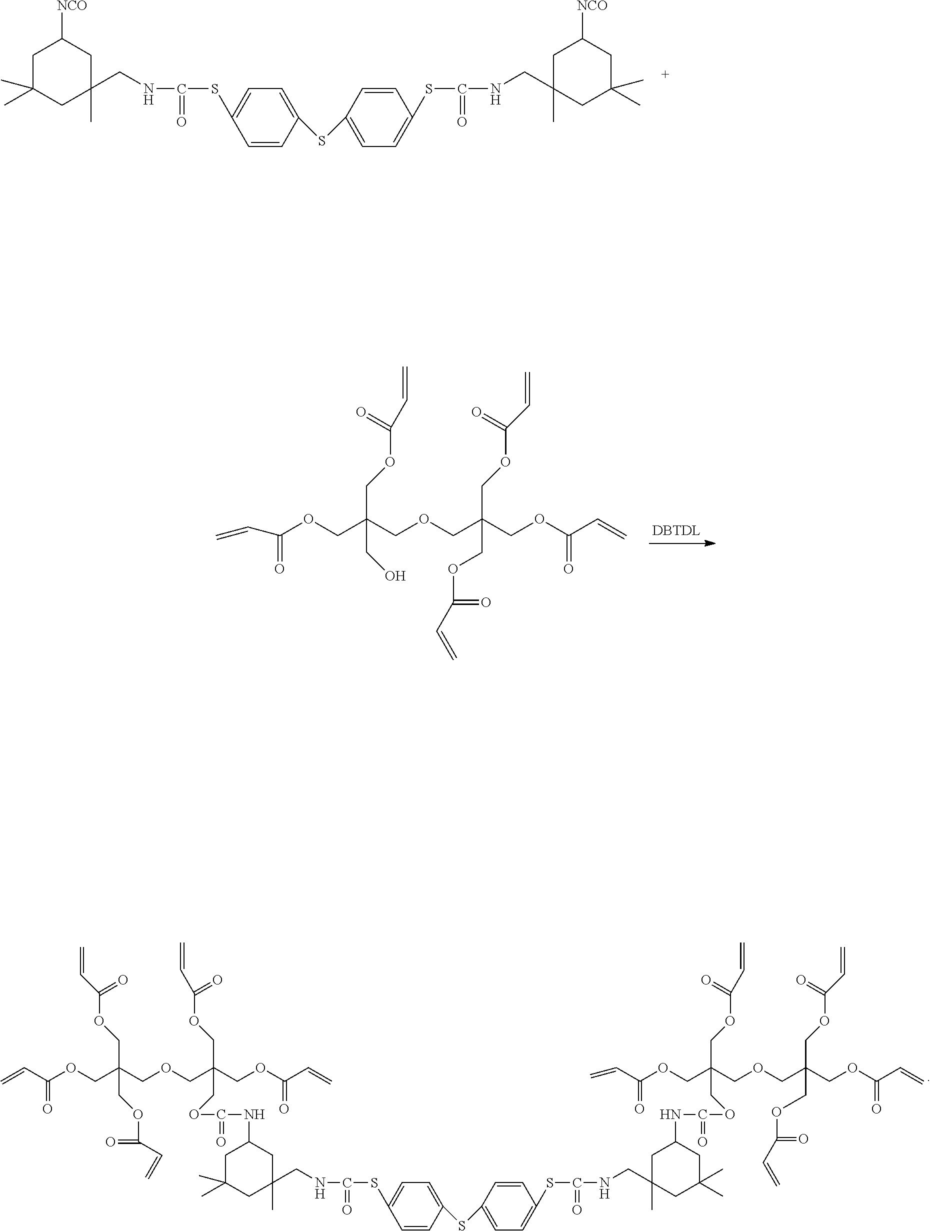

In the third compound, R₁ contains aromatic rings and sulfur atoms, making the third compound have higher molar refractive index, and further improving the refractive index of the optical thin film made of the optical thin film material including the first compound, the second compound, and the third compound. Moreover, both of R₁ and R₂ in the third compound contain a large number of acryloyloxy groups, which can effectively improve the cross-linking degree of the third compound and the first compound and the second compound in the cross-linking polymerization reaction for forming the optical thin film, improving the mechanical performance and stability of the optical thin film made of the optical thin film material including these compounds, and further improving its resistance to high and low temperature, high temperature and humidity, and cold and hot shock.

Furthermore, the first compound may be contained in the optical thin film material in an amount of 50 to 100 parts by mass, the second compound may be contained in the optical thin film material in an amount of 0 to 50 parts by mass, and the third compound may be contained in the optical thin film material in an amount of 0 to 50 parts by mass.

Furthermore, the optical thin film material may be a photocurable material, and the optical thin film material may further include a photoinitiator. In some embodiments, the optical thin film material further includes a reactive diluent to adjust the viscosity of the optical thin film material.

In some embodiments, the reactive diluent includes a first reactive diluent containing a monofunctional group and/or a second reactive diluent containing a double functional group. For example, the first reactive diluent may be selected from hydroxyethyl (meth)acrylate, isobornyl (meth)acrylate, 2-phenoxyethyl acrylate, lauryl acrylate, tetrahydrofuran acrylate, or the like; and the second reactive diluent may be selected from di(ethylene glycol) diacrylate, tri(ethylene glycol) diacrylate, poly(ethylene glycol) diacrylate, di(propylene glycol) diacrylate, tri(propylene glycol) diacrylate, tricyclodecane dimethanol diacrylate, neopentyl glycol diacrylate, 1,6-hexanediol diacrylate, or the like.

The photoinitiator may include a I-type photoinitiator and/or an II-type photoinitiator. The I-type photoinitiator may be used to decompose molecules to produce free radicals due to differences in chemical structure or binding energy of the moleculars. Tertiary amines are introduced in the II-type photoinitiator (a hydrogen grabbing photoinitiator) as co initiators. Specifically, the I-type photoinitiator may be selected from an acetophenone-based photoinitiator and/or a benzoin-based photoinitiator. For example, the acetophenone-based photoinitiator may be selected from 4-phenoxydichlorophenone, 4-tert-butyl dichlorophenone, 4-tert-butyl trichlorophenone, diethoxyacetophenone, 2-hydroxy-2-methyl-1-phenylpropyl-1-one, 1-(4-isopropylphenyl)-2-hydroxy-2-methylpropyl-1-one, 1-(4-dodecylphenyl)-2-hydroxy-2-methylpropyl-1-one, 4-hydroxy (2-hydroxyethoxy) phenyl (2-hydroxy-2-propyl) ketone, 1-hydroxycyclohexyl phenyl ketone, or the like; and the benzoin-based photoinitiator may be selected from benzoin methyl ether, benzoin ethyl ether, benzyl dimethyl ketal, or the like. The II-type photoinitiator may be selected from a benzophenone-based photoinitiator and/or a thioxanthone-based photoinitiator. For example, the benzophenone-based photoinitiator may be selected from benzophenone, benzoylbenzoic acid, benzoylbenzoic acid methyl ether, 4-phenylbenzophenone, hydroxybenzophenone, 4-benzoyl-4′-methyldiphenyl sulfide, 3,3′-dimethyl-4-methoxybenzophenone, or the like; and the thioxanthone-based photoinitiator may be selected from thioxanthone, 2-chlorothioxanthone, 2-methylthioxanthone, 2,4-dimethylthioxanthone, isopropylthioxanthone, or the like. The photoinitiator of the present disclosure may be selected from at least one of the above-mentioned photoinitiators.

In some embodiments, the reactive diluent may be contained in the optical thin film material in an amount of 10 to 30 parts by mass, and the photoinitiator may be contained in the optical thin film material in an amount of 1 to 10 parts by mass.

At step S20, the first compound, the second compound, the third compound, the photoinitiator, and the reactive diluent are mixed to form a mixture.

Then, the above-mentioned mixture is coated to obtain an intermediate film. Coating methods such as roller coating and/or micro concave roller coating may be used.

Next, the intermediate film is cured to obtain the optical thin film. Specifically, UV curing may be used to form the optical thin film, and the energy of UV light may range between 500 mj/cm² and 1000 mj/cm².

It can be understood that during the above-mentioned curing process, the first compound, the second compound, and the third compound may undergo the cross-linking polymerization to obtain a polymer to form the optical thin film containing the polymer.

Embodiments of the present disclosure can greatly improve the refractive index of the optical thin film by designing both of the first compound and the second compound containing a large number of aromatic rings and/or sulfur atoms. Moreover, because the third compound contains aromatic rings, the refractive index of the optical thin film can further be improved to a certain degree. Furthermore, the third compound contains a large number of acryloyloxy groups, which can improve the crosslinking degree of the polymer in the formation process of the optical thin film, and further improve stability and tolerance performance of the optical thin film.

In some embodiments of the present disclosure, the refractive index of the optical thin film may be greater than or equal to 1.5 and less than or equal to 1.8.

Furthermore, the present disclosure provides examples 1-7 to test the refractive index of optical thin films prepared by the above-mentioned preparation method, and obtain the experimental results shown in table 2.

TABLE 2

| | First compound/ | Second compound/ | Third compound/ | Reactive diluent/ | Photoinitiator/ | Refractive |
|---|---|---|---|---|---|---|
| Example | parts by mass | parts by mass | parts by mass | parts by mass | parts by mass | index |
| Example 1 | 50 | 50 | 20 | 2-phenoxyethyl | 1- | 1.66 |
| | | | | acrylate/10 | hydroxycyclohexyl | |
| | | | | | phenyl ketone/4 | |
| Example 2 | 100 | 10 | 5 | 2-phenoxyethyl | 1- | 1.73 |
| | | | | acrylate/5 | hydroxycyclohexyl | |
| | | | | | phenyl ketone/4 | |
| Example 3 | 50 | 10 | 50 | Tricyclodecane | 4-hydroxy (2- | 1.63 |
| | | | | dimethanol | hydroxyethoxy) | |
| | | | | diacrylate /10 | phenyl (2-hydroxy- | |
| | | | | | 2-propyl) ketone/5 | |
| Example 4 | 100 | 0 | 5 | 2-phenoxyethyl | 1- | 1.78 |
| | | | | acrylate/5 | hydroxycyclohexyl | |
| | | | | | phenyl ketone/4 | |
| Example 5 | 50 | 10 | 50 | Tricyclodecane | 4-hydroxy (2- | 1.58 |
| | | | | dimethanol | hydroxyethoxy) | |
| | | | | diacrylate /30 | phenyl (2-hydroxy- | |
| | | | | | 2-propyl) ketone/5 | |
| Example 6 | 50 | 0 | 0 | 2-phenoxyethyl | 1- | 1.80 |
| | | | | acrylate/10 | hydroxycyclohexyl | |
| | | | | | phenyl ketone/1 | |
| Example 7 | 100 | 50 | 50 | Tricyclodecane | 4-hydroxy (2- | 1.53 |
| | | | | dimethanol | hydroxyethoxy) | |
| | | | | diacrylate /30 | phenyl (2-hydroxy- | |
| | | | | | 2-propyl) | |
| | | | | | ketone/10 | |

It can be seen from table 2 that the embodiments of the present disclosure can effectively improve the refractive index of the optical thin film made of the optical thin film material, to obtain the optical thin film with higher refractive index.

Embodiments of the present disclosure further provide a display panel, which includes an optical thin film prepared using the preparation method of the optical thin film described in the above-mentioned embodiments.

The display panel may be an organic light-emitting diode (OLED) display panel.

In some embodiment, the display panel includes an encapsulation layer including the optical thin film. That is, the optical thin film can be reused as the encapsulation layer, while improving the light extraction effect of the organic light-emitting device in the OLED display panel.

Referring to FIG. 2, in some embodiments, a display panel 10 includes an anti-reflective layer 12 disposes on a light-emitting surface of a panel body 11. The anti-reflective film 12 includes a substrate layer 121 disposed on the light-emitting surface of the panel body 11, an optical thin film 122 disposed on a side of the substrate layer 121 away from the panel body 11, and a low refractive index layer 123 disposed on a side of the optical thin film 122 away from the substrate layer 121. A refractive index of the low refractive index layer 123 is less than the refractive index of the optical thin film 122.

In view of forgoing, the optical thin film material provided by the embodiments of the present disclosure can be used to form the optical thin film with higher refractive index, by introducing the aromatic ring and/or the sulfur atom to effectively improve the refractive index of the optical thin film material. Moreover, since none of halogen atoms and nanoparticles are introduced in the optical thin film material, the present disclosure avoids the halogen atoms being restricted for use due to toxicity and corrosive gases generated during the combustion of the material containing the halogen atoms, and eliminates the adverse effects of the nanoparticles on light scattering.

In the above-mentioned embodiments, the description of each embodiment has its own emphasis. For the parts that are not detailed in one embodiment, please refer to the relevant descriptions of other embodiments.

The optical thin film material, the preparation method of the optical thin film, and the display panel using the preparation method provided by the embodiments of the present disclosure are described in detail. In this paper, specific embodiments are adopted to illustrate a principle and implementation modes of the present disclosure. The description of the above-mentioned embodiments is only used to help understand methods and a core idea of the present disclosure. At the same time, for those skilled in the art, according to the idea of the present disclosure, there will be changes in specific implementation modes and a scope of the present disclosure. In conclusion, contents of the specification should not be interpreted as a limitation of the present disclosure.

What is claimed is:

1. An optical thin film material comprising a compound, wherein the compound is represented by formula (1): 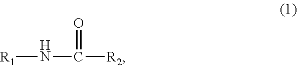
wherein one of R₁ and R₂ comprises an aromatic ring and/or a sulfur atom, and another of R₁ and R₂ comprises at least one of an acryloyloxy group, an aromatic ring, and a sulfur atom.

2. The optical thin film material of claim 1, wherein both of R₁ and R₂ comprise an acryloyloxy group.

3. The optical thin film material of claim 1, comprising at least one of a first compound, a second compound, and a third compound;
wherein the first compound is represented by following structure: 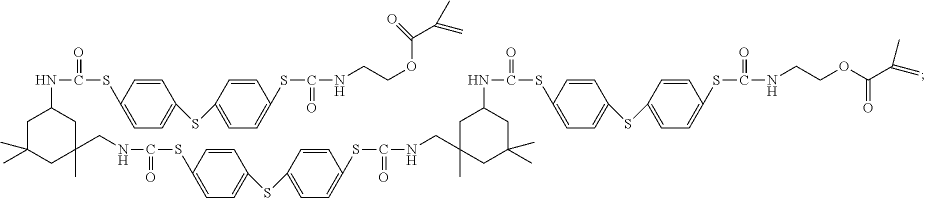 [SMILES: C=C(C)C(=O)OCCNC(=O)Sc1ccc(Sc2ccc(SC(=O)NC3CC(C)(C)CC(C)(CNC(=O)Sc4ccc(Sc5ccc(SC(=O)NCC6(C)CC(NC(=O)Sc7ccc(Sc8ccc(SC(=O)NCCOC(=O)C(=C)C)cc8)cc7)CC(C)(C)C6)cc5)cc4)C3)cc2)cc1]
wherein the second compound is represented by following structure: 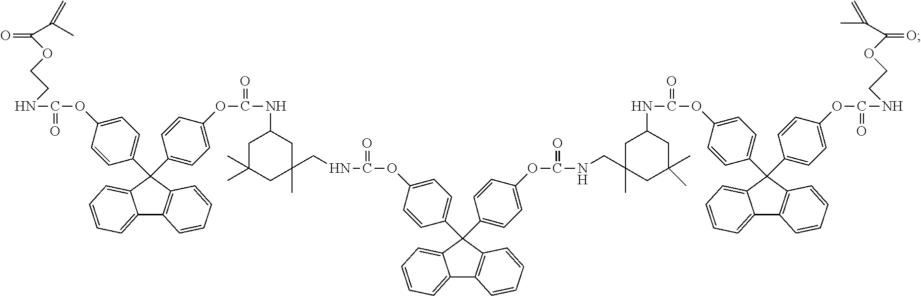 [SMILES: C=C(C)C(=O)OCCNC(=O)Oc1ccc(C2(c3ccc(OC(=O)NC4CC(C)(C)CC(C)(CNC(=O)Oc5ccc(C6(c7ccc(OC(=O)NCC8(C)CC(NC(=O)Oc9ccc(C%10(c%11ccc(OC(=O)NCCOC(=O)C(=C)C)cc%11)c%11ccccc%11-c%11ccccc%11%10)cc9)CC(C)(C)C8)cc7)c7ccccc7-c7ccccc76)cc5)C4)cc3)c3ccccc3-c3ccccc32)cc1]
and
wherein the third compound is represented by following structure:

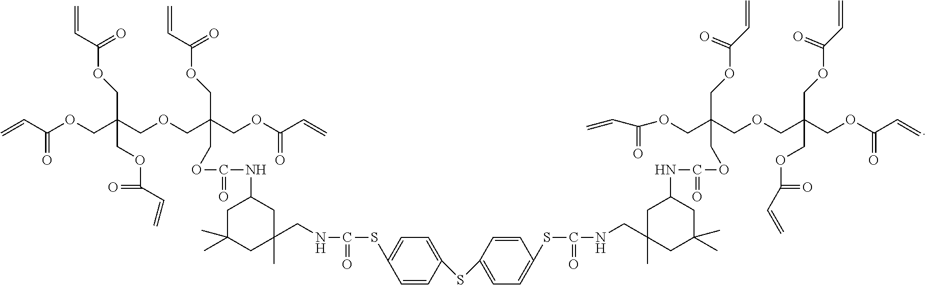 [SMILES: C=CC(=O)OCC(COCC(COC(=O)C=C)(COC(=O)C=C)COC(=O)NC1CC(C)(C)CC(C)(CNC(=O)Sc2ccc(Sc3ccc(SC(=O)NCC4(C)CC(NC(=O)OCC(COCC(COC(=O)C=C)(COC(=O)C=C)COC(=O)C=C)(COC(=O)C=C)COC(=O)C=C)CC(C)(C)C4)cc3)cc2)C1)(COC(=O)C=C)COC(=O)C=C]

4. The optical thin film material of claim 3, wherein the first compound is contained in the optical thin film material in an amount of 50 to 100 parts by mass, the second compound is contained in the optical thin film material in an amount of 0 to 50parts by mass, and the third compound is contained in the optical thin film material in an amount of 0 to 50 parts by mass.

5. The optical thin film material of claim 3, further comprising a reactive diluent and photoinitiator, wherein the reactive diluent comprises a first reactive diluent containing a monofunctional group and/or a second reactive diluent containing a bifunctional group.

6. The optical thin film material of claim 5, wherein the reactive diluent is contained in the optical thin film material in an amount of 10 to 30 parts by mass, and the photoinitiator is contained in the optical thin film material in an amount of 1 to 10parts by mass.

7. The optical thin film material of claim 5, wherein the first reactive diluent is selected from hydroxyethyl (meth)acrylate, isobornyl (meth)acrylate, 2-phenoxyethyl acrylate, lauryl acrylate, or tetrahydrofuran acrylate; and
wherein the second reactive diluent is selected from di(ethylene glycol) diacrylate, tri(ethylene glycol) diacrylate, poly(ethylene glycol) diacrylate, di(propylene glycol) diacrylate, tri(propylene glycol) diacrylate, tricyclodecane dimethanol diacrylate, neopentyl glycol diacrylate, or 1,6-hexanediol diacrylate.

8. The optical thin film material of claim 5, wherein the photoinitiator comprises a I-type photoinitiator and/or an II-type photoinitiator;
wherein the I-type photoinitiator is selected from an acetophenone-based photoinitiator and/or a benzoin-based photoinitiator; and
wherein the II-type photoinitiator is selected from a benzophenone-based photoinitiator and/or a thioxanthone-based photoinitiator.

9. The optical thin film material of claim 8, wherein the acetophenone-based photoinitiator is selected from 4-phenoxydichlorophenone, 4-tert-butyl dichlorophenone, 4-tert-butyl trichlorophenone, diethoxyacetophenone, 2-hydroxy-2-methyl-1-phenylpropyl-1-one, 1-(4-isopropylphenyl)-2-hydroxy-2-methylpropyl-1-one, 1-(4-dodecylphenyl)-2-hydroxy-2-methylpropyl-1-one, 4-hydroxy (2-hydroxyethoxy) phenyl (2-hydroxy-2-propyl) ketone, or 1-hydroxycyclohexyl phenyl ketone; and the benzoin-based photoinitiator is selected from benzoin methyl ether, benzoin ethyl ether, or benzyl dimethyl ketal; and
the benzophenone-based photoinitiator is selected from benzophenone, benzoylbenzoic acid, benzoylbenzoic acid methyl ether, 4-phenylbenzophenone, hydroxybenzophenone, 4-benzoyl-4′-methyldiphenyl sulfide, or 3,3′-dimethyl-4-methoxybenzophenone; and the thioxanthone-based photoinitiator is selected from thioxanthone, 2-chlorothioxanthone, 2-methylthioxanthone, 2,4-dimethylthioxanthone, or isopropylthioxanthone.

10. A preparation method of an optical thin film, comprising following steps:
providing an optical thin film material comprising a compound, wherein the compound is represented by formula (1): 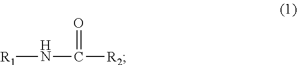
wherein one of R₁ and R₂ comprises an aromatic ring and/or a sulfur atom, and another of R₁ and R₂ comprises at least one of an acryloyloxy group, an aromatic ring, and a sulfur atom; and
forming the optical thin film using the optical thin film material.

11. The preparation method of the optical thin film of claim 10, further comprising following steps:
providing a reactive diluent and a photoinitiator;
mixing the optical thin film material, the reactive diluent, and the photoinitiator to obtain a mixture;
coating the mixture to obtain an intermediate film; and
curing the intermediate film to obtain the optical thin film.

12. The preparation method of the optical thin film of claim 10, wherein a refractive index of the optical thin film is greater than or equal to 1.5 and less than or equal to 1.8.

13. The preparation method of the optical thin film of claim 10, wherein both of R₁ and R₂ comprise an acryloyloxy group.

14. The preparation method of the optical thin film of claim 10, wherein the optical thin film material comprises at least one of a first compound, a second compound, and a third compound;
wherein the first compound is represented by following structure: 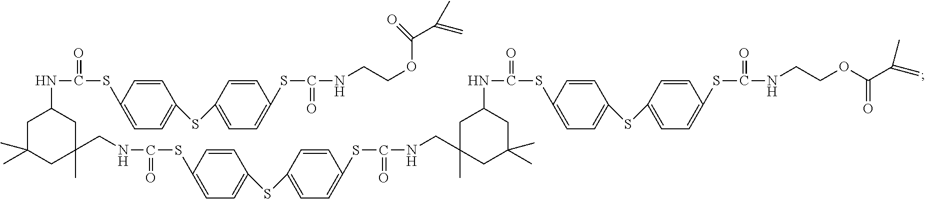 [SMILES: C=C(C)C(=O)OCCNC(=O)Sc1ccc(Sc2ccc(SC(=O)NC3CC(C)(C)CC(C)(CNC(=O)Sc4ccc(Sc5ccc(SC(=O)NCC6(C)CC(NC(=O)Sc7ccc(Sc8ccc(SC(=O)NCCOC(=O)C(=C)C)cc8)cc7)CC(C)(C)C6)cc5)cc4)C3)cc2)cc1]
wherein the second compound is represented by following structure: 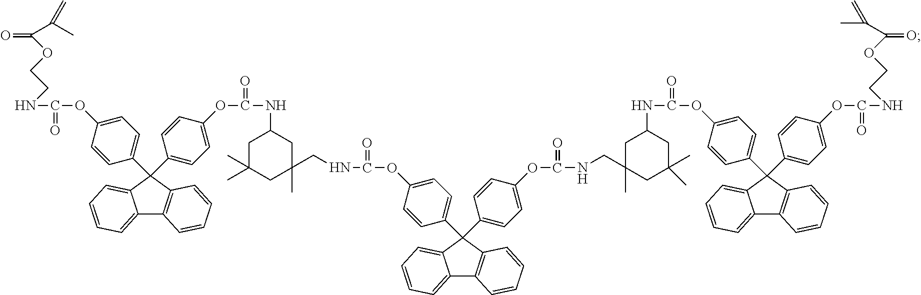 [SMILES: C=C(C)C(=O)OCCNC(=O)Oc1ccc(C2(c3ccc(OC(=O)NC4CC(C)(C)CC(C)(CNC(=O)Oc5ccc(C6(c7ccc(OC(=O)NCC8(C)CC(NC(=O)Oc9ccc(C%10(c%11ccc(OC(=O)NCCOC(=O)C(=C)C)cc%11)c%11ccccc%11-c%11ccccc%11%10)cc9)CC(C)(C)C8)cc7)c7ccccc7-c7ccccc76)cc5)C4)cc3)c3ccccc3-c3ccccc32)cc1]
and
wherein the third compound is represented by following structure:

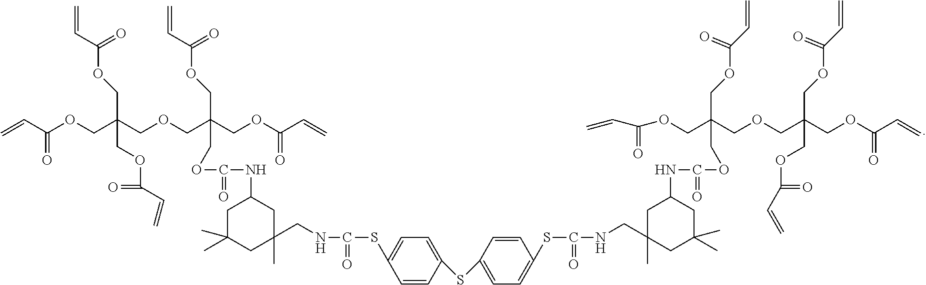 [SMILES: C=CC(=O)OCC(COCC(COC(=O)C=C)(COC(=O)C=C)COC(=O)NC1CC(C)(C)CC(C)(CNC(=O)Sc2ccc(Sc3ccc(SC(=O)NCC4(C)CC(NC(=O)OCC(COCC(COC(=O)C=C)(COC(=O)C=C)COC(=O)C=C)(COC(=O)C=C)COC(=O)C=C)CC(C)(C)C4)cc3)cc2)C1)(COC(=O)C=C)COC(=O)C=C]

15. The preparation method of the optical thin film of claim 14, wherein the first compound is contained in the optical thin film material in an amount of 50 to 100 parts by mass, the second compound is contained in the optical thin film material in an amount of 0 to 50 parts by mass, and the third compound is contained in the optical thin film material in an amount of 0 to 50 parts by mass.

16. The preparation method of the optical thin film of claim 14, further comprising a reactive diluent and photoinitiator, wherein the reactive diluent comprises a first reactive diluent containing a monofunctional group and/or a second reactive diluent containing a bifunctional group.

17. The preparation method of the optical thin film of claim 16, wherein the reactive diluent is contained in the optical thin film material in an amount of 10 to 30parts by mass, and the photoinitiator is contained in the optical thin film material in an amount of 1 to 10 parts by mass.

18. The preparation method of the optical thin film of claim 16, wherein the first reactive diluent is selected from hydroxyethyl (meth)acrylate, isobornyl (meth)acrylate, 2-phenoxyethyl acrylate, lauryl acrylate, or tetrahydrofuran acrylate; and
wherein the second reactive diluent is selected from di(ethylene glycol) diacrylate, tri(ethylene glycol) diacrylate, poly(ethylene glycol) diacrylate, di(propylene glycol) diacrylate, tri(propylene glycol) diacrylate, tricyclodecane dimethanol diacrylate, neopentyl glycol diacrylate, or 1,6-hexanediol diacrylate.

19. The preparation method of the optical thin film of claim 16, wherein the photoinitiator comprises a I-type photoinitiator and/or an II-type photoinitiator;
wherein the I-type photoinitiator is selected from an acetophenone-based photoinitiator and/or a benzoin-based photoinitiator; and
wherein the II-type photoinitiator is selected from a benzophenone-based photoinitiator and/or a thioxanthone-based photoinitiator.

20. A display panel comprising an optical thin film, wherein a preparation method of the optical thin film comprises following steps:
providing an optical thin film material comprising a compound, wherein the compound is represented by formula (1): 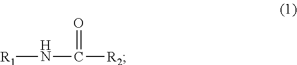
wherein one of R₁ and R₂ comprises an aromatic ring and/or a sulfur atom, and another of R₁ and R₂ comprises at least one of an acryloyloxy group, an aromatic ring, and a sulfur atom; and
forming the optical thin film using the optical thin film material.
